(19) United States
(12) Patent Application Publication
(10) Pub. No.: US 2011/0169162 A1
(43) Pub. Date: Jul. 14, 2011

(54) Integrated Circuit Module and Multichip Circuit Module Comprising an Integrated Circuit Module of This Type

(76) Inventors: Torben Baras, Braunschweig (DE); Arne F. Jacob, Braunschweig (DE)

(21) Appl. No.: 11/573,015

(22) PCT Filed: Sep. 23, 2004
(86) PCT No.: PCT/DE2004/002108

§ 371 Date: Oct. 17, 2008

(51) Int. Cl. H01L 23/498; H01L 23/48

(52) U.S. Cl. 257/738; 257/774; 257/E23.011; 257/E23.069

(57) ABSTRACT

The invention relates to an integrated circuit module (3) comprising a carrier substrate (4) with terminals for electrically contacting the carrier substrate (4) and a motherboard (2) and comprising at least one semiconductor chip (9) that is electrically contacted to the carrier substrate (4) and integrated into the substrate (4). The carrier substrate (4) comprises at least one cavity (8) that adjoins a mounting surface (10) for the motherboard (2) and holds at least one semiconductor chip (9). The cavity (8) is equipped with connection contacts (11a, 11b) for assigned connections of the semiconductor chip or chips (9), said contacts electrically contacting the semiconductor chip (9) and the carrier substrate (4). The carrier substrate (4) is multi-layered and comprises conductor tracks that extend transversally through several layers and the cavity (8) is hermetically sealed by a thermally conductive cover (12).

The invention relates to an integrated circuit module comprising a carrier substrate with terminals for electrically contacting the carrier substrate with respect to a main board and comprising at least one semiconductor chip that is electrically contacted with respect to the carrier substrate and integrated into the carrier substrate, the carrier substrate having at least one cavity, which adjoins a mounting surface for the main board and is intended for holding at least one semiconductor chip, and terminal contacts for assigned terminals of the at least one semiconductor chip being provided in the cavity for the electrical contacting of the semiconductor chip with respect to the carrier substrate.

The invention also relates to a multichip circuit module comprising a main board, at least one carrier substrate mounted on the main board and electrically contacted with respect to the main board and at least one semiconductor chip on the carrier substrate to form an integrated circuit module, the semiconductor chip being electrically contacted with respect to the carrier substrate, the carrier substrate having at least one cavity for holding at least one semiconductor chip on a mounting surface for the main board, terminal contacts for assigned terminals of the at least one semiconductor chip being provided in the cavity for the electrical contacting of the semiconductor chip with respect to the carrier substrate, and the mounting surface of the carrier substrate being applied to a contact surface of the main board.

Multichip circuit modules are sufficiently well-known, for example from DE 100 11 005 A1 and DE 100 41 770 A1. In particular, radio-frequency circuits in the frequency range up to 100 GHz are realized in the form of such multichip circuit modules. The multichip circuit modules in these cases comprise a carrier substrate on which individual semiconductor chips are mounted by wire bonding or flip-chip technology. Suitable semiconductor chips may be for example Millimeter Wave Monolithic Integrated Circuits MMIC. The carrier substrate may also have passive circuit components, for example on the surface or in deep levels of the carrier substrate. For radio-frequency use, the carrier substrate may be for example a multilayer ceramic, such as for example Low Temperature Cofired Ceramics LTCG.

The carrier substrates with the passive and active circuit components in turn form submodules, which are grouped together on a further substrate, the main board. The submodules are electrically contacted with respect to the main board and consequently also with respect to one another.

For the contacting of the carrier substrate with respect to the main board, there is for example the Ball Grid Array BGA connecting technique known from DE 199 31 004 A1.

The multichip circuit module is subsequently encapsulated with dielectric filling material, as disclosed in DE 101 16 510 A1, or is shielded with a metal package, as described in DE 100 59 688 A1.

EP 0 900 477 131 describes an electronic component with surface wave filters in which a carrier substrate is mounted on a main board by the flip-chip technique. A metallic protective layer is directly applied on the side of the carrier substrate that is facing away from the connecting region between the carrier substrate and the main board, up to the main board, so that there is a tight seal with respect to the main board.

The flip-chip technique for the electrical contacting of semiconductor chips on a carrier substrate or of a carrier substrate on a main board with the aid of bumps that are connected to terminal contacts is described for example in DE 100 41 695 A1, DE 100 43 450 A1 and DE 100 29 255 A1.

Shielding the multichip circuit modules disadvantageously requires additional working steps.

DE 196 40 192 A1 describes a method for the bump-free flip-chip mounting of integrated circuits on a substrate using anisotropically conductive adhesives.

JP 2003174141 A1 discloses a multichip circuit module in which a semiconductor chip is connected to bumps that are conductively routed on a level of a carrier substrate to terminal contacts in cavities of the carrier substrate. The mounting surface of the carrier substrate is connected by interposed filling material to the contact surface of a main board, so that the semiconductor chip is encapsulated. The electrical contacting of the carrier substrate is performed by way of the cavities with respect to the main board.

The problem of conventional multichip circuit modules is that the semiconductors are only encapsulated and protected when mounting on the main board is carried out. This imposes greater requirements on the storage and mounting of the integrated circuit modules with the main board.

The object of the invention is therefore to provide an improved integrated circuit module and an improved multichip circuit module with such an integrated circuit module that is hermetically encapsulated and nevertheless allows good heat dissipation.

The object is achieved with the integrated circuit module of the generic type and the multichip circuit module of the generic type by the carrier substrate being multilayered, with conductor tracks extending transversely through a number of layers, and by the cavity in the multilayered carrier substrate being sealed with a hermetic and thermally conductive covering.

The arrangement of the semiconductor chips in the cavity adjoining the mounting surface for the main board ensures good direct heat removal onto the main board and hermetic encapsulation of the integrated circuit module by the hermetic and thermally conductive covering. It is consequently essential that the cavity directly adjoins the main board. During the production of the integrated circuit module, it can be hermetically sealed by the covering after contacting of the at least one semiconductor chip held in the cavity, so that the integrated circuit module is protected and relatively robust.

Preferably, thermally conductive contact material is provided between the at least one semiconductor chip and the covering in the cavity. This allows differences in height of the at least one semiconductor chip to be compensated and good thermal coupling between the covering and the semiconductor chip to be ensured.

Furthermore, it is advantageous if thermally conductive contact material is provided between the covering and the main board to provide direct thermal coupling between the covering and the main board.

In the main board, thermal vias that adjoin the covering and/or the thermally conductive contact material on the covering may be preferably provided for the heat removal through the main board to a heat sink of the main board.

The carrier substrate is preferably contacted directly with respect to the main board, the mounting surface of the carrier substrate directly adjoining the main board.

Optionally or in addition to this, the carrier substrate may also be contacted with respect to the main board by ball grid arrays. Ball grid arrays are soldered connections with micro solder balls, which are arranged at contact points spaced apart from one another in the manner of an array. The ball grid array soldering technique is sufficiently well known from microtechnology.

For further improved heat removal, the carrier substrate may be recessed in a clearance in the main board and directly adjoin a heat sink of the main board. Consequently, the heat no longer has to be conducted for example through thermal vias through the electrically insulating layer of the main board to the heat sink, but can be removed directly.

The electrical connection of the integrated circuit module to the main board may take place for example by a field coupling between the terminals of the carrier substrate and the main board. This field coupling may be realized by terminals of the carrier substrate and of the main board that are parallel to one another or overlap.

The carrier substrate may, however, also have terminals in the region of the contact surface of the main board that are connected directly or by bonding connections to assigned terminals of the main board.

The invention is explained in more detail below by way of example on the basis of the accompanying drawings, in which:

FIG. 1 shows a cross-sectional representation of a first embodiment of the multichip circuit module according to the invention;

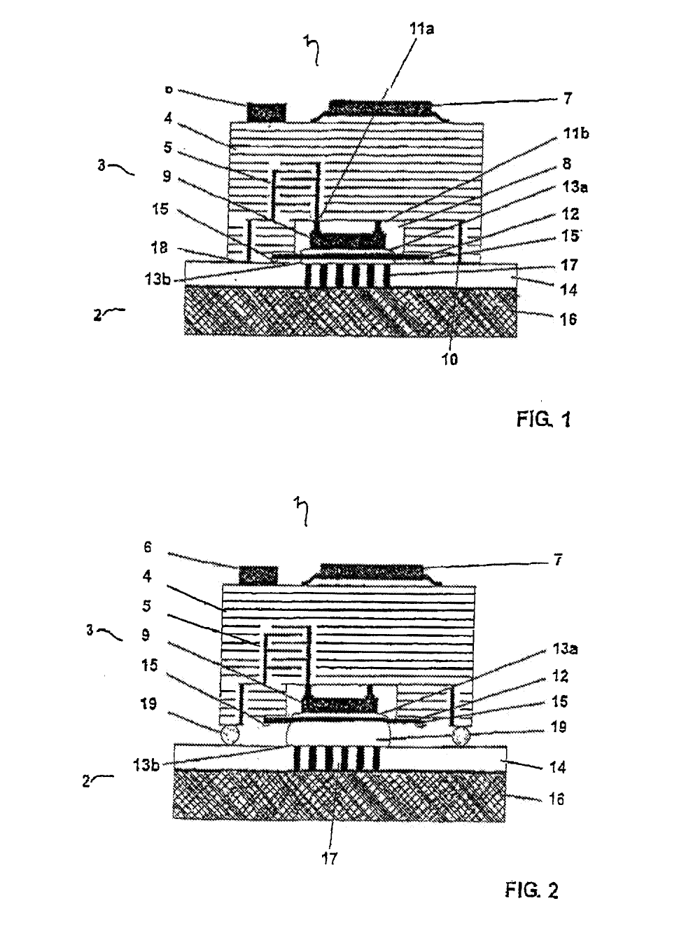

FIG. 2 shows a cross-sectional representation of a second embodiment of the multichip circuit module according to the invention with ball grid array contacts;

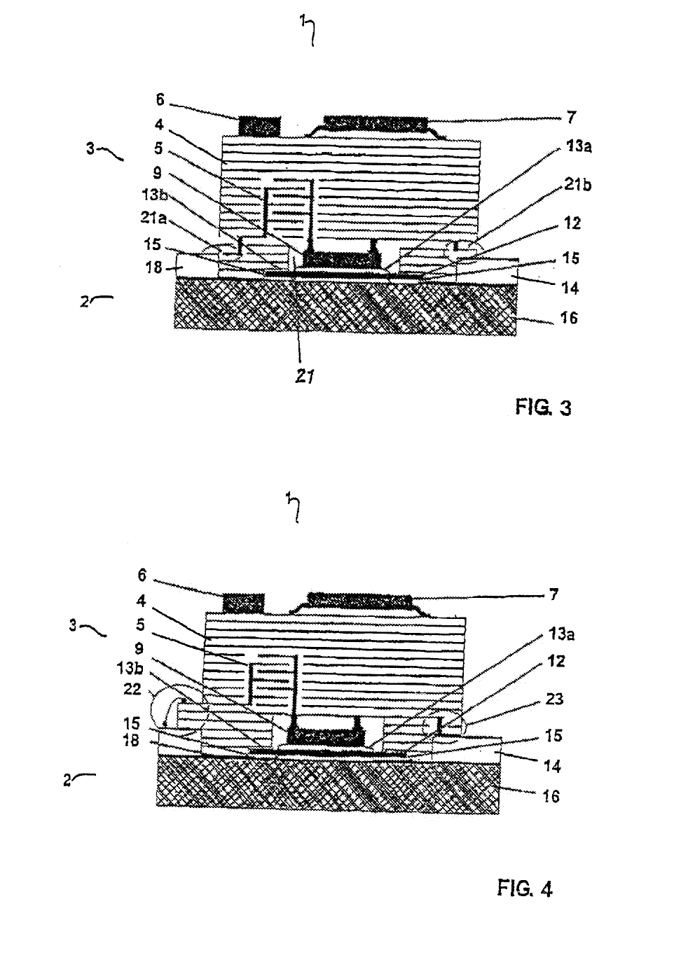

FIG. 3 shows a cross-sectional view of a third embodiment of the multichip circuit module according to the invention with a carrier substrate recessed into the main board and a field coupling;

FIG. 4 shows a cross-sectional view of a fourth embodiment of the multichip circuit module according to the invention with a carrier substrate recessed into the main board and direct contacting.

FIG. 1 illustrates a cross-sectional view of a first embodiment of a multichip circuit module 1 with an integrated circuit module 3 applied to a main board 2. The integrated circuit module 3 has a multilayered carrier substrate 4, into which passive components 5 may be integrated. Furthermore, hermetically encapsulated active or passive components 6, 7 may be attached on the surface of the carrier substrate 4.

At least one cavity 8 for holding at least one semiconductor chip 11 may be provided in the carrier substrate 4, on a mounting surface 10 of the carrier substrate 4 for the main board 2. The at least one component is electrically contacted with respect to assigned terminal contacts 11a, 11b of the carrier substrate 4 on the inner side of the cavity 8.

The cavity 8 is sealed by a hermetically and thermally conductive covering 12. During the production of the integrated circuit module 3, it is already hermetically sealed with the covering 12, so that in the subsequent processing stages lower requirements have to be imposed on the storage and mounting of the integrated circuit module 3 with the main board 2.

The thermally conductive covering 12 also provides good heat removal of the thermal energy from the semiconductor chip 9 to the main board 2. The thermal coupling can be improved by thermally conductive contact material 13a, 13b between the semiconductor chip 9 and the covering 12 and also between the covering 12 and the electrical insulating layer 14 of the main board 2. The thermally conductive contact material 13a, 13b can also be used to compensate for variations in height of the mounted semiconductor chip 9.

The sealing between the covering 12 and the multilayered carrier substrate 4 may take place with a hermetic seal 15, which is arranged for example at the peripheral edge of the covering 12.

The heat flux through the electrically insulating layer 14, which at the same time is also generally a poor heat conductor, to a heat sink 16 of the main board 2 can be improved by thermal vias 17, which, adjoining the covering 12, extend through the electrically insulating layer 14 of the main board 2 to the heat sink 16.

In the embodiment represented, the integrated circuit module 3 is electrically connected to the main board 2 by means of direct contacting 18 and substantially rests directly on the main board 2.

FIG. 2 shows a second embodiment of the multichip circuit module 1, in which the integrated circuit module 3 does not rest directly on the substrate 2 but is electrically contacted with respect to the main board 2 by use of a ball grid array (BGA) 19. This has the effect that there is a distance between the integrated circuit module 3 and the main board 2, which is compensated by the thermally conducting contact material 13b.

FIG. 3 illustrates a third embodiment of the multichip circuit module 1, in which the hermetically sealed integrated circuit module 3 is recessed into a clearance 20 in the main board 2, in particular in the electrically insulating layer 14. This has the advantage that the heat generated by the semiconductor chip 9 is passed via the electrical contact material 13a, 13b and the covering 12 directly into the heat sink 16 of the main board 2. This dispenses with the thermal impedance of the electrically insulating layer 14 of the main board and the thermal impedance of the thermal vias 17 in the path between the semiconductor chip 9 and the heat sink 16.

The integrated circuit module 3 may be connected to the main board 2 by way of a parallel field coupling 21a or a field coupling by overlap 21b. In the case of the parallel field coupling 21a, the ends of the assigned electrical terminals of the integrated circuit module 3 and of the main board 2 are directly opposite one another, without touching and establishing a direct electrical contact. In the case of the field coupling by overlap 21b, the terminals of the integrated circuit module and of the main board 2 overlap, but without touching.

FIG. 4 illustrates a fourth embodiment of the multichip circuit module 1, in which the integrated circuit module 3 is in turn recessed into a clearance in the electrically insulating layer 14 of the main board 2. The electrical contacting of the integrated circuit module with respect to the main board 2 takes place in this case by means of bonding connection 22 or by means of direct contacting by overlapping terminals 23 and, if appropriate, direct contacting 18.

The multichip circuit modules 1 represented, hermetically sealed by a thermally conductive covering 12, are robust under environmental influences, on account of the hermetic encapsulation of the embedded semiconductor chips 9 in the multilayered carrier substrate 4. The encapsulation, already performed before the integrated circuit module 3 is mounted on a carrier, allows simple storage, further processing and possible testing, for example burn-in. The simultaneous good heat removal makes it possible to use power semiconductors in the integrated circuit module 3. On account of the compatibility with standard industrial processes, the multichip circuit module 1 can also be produced at low cost. Moreover, on account of the freedom of design of the interface between the integrated circuit module 3 and the main board 2, application-adapted transitions are possible.

1. An integrated circuit module (3) comprising a carrier substrate (4) with terminals for electrically contacting the carrier substrate (4) with respect to a main board (2) and comprising at least one semiconductor chip (9) that is electrically contacted with respect to the carrier substrate (4) and integrated into the carrier substrate (4), the carrier substrate (4) having at least one cavity (8), which adjoins a mounting surface (10) for the main board (2) and is intended for holding at least one semiconductor chip (9), and terminal contacts for assigned terminals of the at least one semiconductor chip (9) being provided in the cavity (8) for the electrical contacting of the semiconductor chip (9) with respect to the carrier substrate (4), characterized in that the carrier substrate (4) is multilayered, with conductor tracks extending transversely through a number of layers, and the cavity (8) is sealed with a hermetic and thermally conductive covering (12).

2. The integrated circuit module (3) as claimed in claim 1, characterized by thermally conductive contact material between the at least one semiconductor chip (9) and the covering (12).

3. The integrated circuit module (3) as claimed in claim 1, characterized by thermally conductive contact material on the surface of the covering (12) that is intended for applying to the main board (2).

4. A multichip circuit module (1) comprising a main board (2), at least one carrier substrate (4) mounted on the main board (2) and electrically least one semiconductor chip (9) on the carrier substrate (4), which is electrically contacted with respect to the carrier substrate (4), the carrier substrate (4) having at least one cavity (8) for holding at least one semiconductor chip (9) on a mounting surface (10) for the main board (2), terminal contacts (11a, 11b) for assigned terminals of the at least one semiconductor chip (9) being provided in the cavity (8) for the electrical contacting of the semiconductor chip (9) with respect to the carrier substrate (4), and the mounting surface (10) of the carrier substrate (4) being applied to a contact surface of the main board (2), characterized in that the carrier substrate (4) is multilayered, with conductor tracks extending transversely through a number of layers, and the cavity (8) is sealed with a hermetic and thermally conductive covering (12).

5. The multichip circuit module (1) as claimed in claim 4, characterized by thermally conductive contact material (13a, 13b) between the at least one semiconductor chip (9) and the covering (12).

6. The multichip circuit module (1) as claimed in claim 4, characterized by thermally conductive contact material (13a, 13b) between the covering (12) and the main board (2).

7. The multichip circuit module (1) as claimed in claim 4, characterized by thermal vias (17) adjoining the covering (12) and/or the thermally conductive contact material (13a, 13b) on the covering (12).

8. The multichip circuit module (1) as claimed in claim 4, characterized in that the carrier substrate (4) is directly contacted with respect to the main board (2) and the mounting surface (10) of the carrier substrate (4) directly adjoins the main board (2).

9. The multichip circuit module (1) as claimed in claim 4, characterized in the carrier substrate (4) is contacted with respect to the main board (2) by ball grid arrays (19).

10. The multichip circuit module (1) as claimed in claim 4, characterized in that the carrier substrate (4) is recessed in a clearance in the main board (2) and directly adjoins a heat sink (16) of the main board (2).

11. The multichip circuit module (1) as claimed in claim 10, characterized by a field coupling (21a, 21b) between the terminals of the carrier substrate (4) and the main board (2).

12. The multichip circuit module (1) as claimed in claim 11, characterized in that the field coupling (21a, 21b) is realized by terminals (23) of the carrier substrate (4) and of the main board (2) that are parallel to one another or overlap.

13. The multichip circuit module (1) as claimed in claim 10, characterized in that the carrier substrate (4) has terminals in the region of the contact surface of the main board (2) arid the terminals are connected directly or by bonding connections to assigned terminals of the main board (2).
